(19) United States
(12) Patent Application Publication
(10) Pub. No.: US 2014/0117354 A1
(43) Pub. Date: May 1, 2014

(54) SEMICONDUCTOR PACKAGE

(71) Applicant: SK HYNIX INC., Icheon-si (KR)

(72) Inventors: Chang-Il KIM, Busan (KR); Sang-Eun LEE, Icheon-si (KR); Sung-Soo RYU, Seongnam-si (KR); Seon-Kwang JEON, Icheon-si (KR)

(73) Assignee: SK HYNIX INC., Icheon-si (KR)

(21) Appl. No.: 13/796,406

(22) Filed: Mar. 12, 2013

(30) Foreign Application Priority Data
Oct. 25, 2012 (KR) 10-2012-0118753

(51) Int. Cl. H01L 23/50

(52) U.S. Cl. CPC H01L 23/50
USPC 257/48; 257/777

(57) ABSTRACT

A semiconductor package including a first semiconductor package including a first terminal and a second terminal provided on a surface different from a surface on which the first terminal is formed, and a second semiconductor package including a third terminal connected to the first terminal, wherein the surface on which the first terminal is formed faces a surface on which the third terminal is formed.

### CROSS-REFERENCE TO RELATED APPLICATIONS

The present application claims priority to Korean Patent Application No. 10-2012-0118753, filed on Oct. 25, 2012, in the Korean Patent Office, which is incorporated herein by reference in its entirety.

### BACKGROUND

1. Technical Field

Various embodiments of the present invention generally relate to a semiconductor package.

2. Related Art

FIG. 1 illustrates an conventional package in which CPU 10 and DRAM 20 are mounted over a substrate 30.

In general, all terminals of the conventional semiconductor package are formed on the bottom thereof, and connected to terminals formed on a substrate 30 with solder balls or other medium.

Such a semiconductor package has a problem in that the area of the substrate 30 is widened with the increase in the number of semiconductor chips, thereby increasing the size of a product. This may serve as an important limiting factor in designing a system such as a mobile device. Furthermore, since signals are transmitted between CPU 10 and DRAM 20 through the substrate 30, interconnections (not illustrated) of the substrate may become complex.

FIG. 2 illustrates another conventional semiconductor package having a CPU 10, DRAM 20, and substrate 30. In this case, the conventional semiconductor package includes a plurality of semiconductor packages stacked vertically. The semiconductor packages may contribute to reducing the area of the system, but heat generated from CPU 10 may have a direct effect on DRAM 20, thereby degrading the stability of the system.

Furthermore, the semiconductor device including the plurality of semiconductor packages stacked vertically therein may have difficulties in reducing the thickness of a system, and thus serve as a limiting factor in designing a system such as a mobile device.

### SUMMARY

Various embodiments are directed to a semiconductor package capable of reducing an area and thickness.

In an embodiment, a semiconductor package includes: a first semiconductor package including a first terminal and a second terminal provided on a surface different from a surface on which the first terminal is formed; and a second semiconductor package including a third terminal connected to the first terminal, wherein the surface on which the first terminal is formed faces a surface on which the third terminal is formed.

The second semiconductor package may furtherer include a fourth terminal provided on a surface different from the surface on which the third terminal is formed.

The first semiconductor package adjacent to the second semiconductor package may have a stepped portion formed therein.

The second semiconductor package adjacent to the first semiconductor package has a stepped portion formed therein.

In an embodiment, a mobile phone including a semiconductor package includes: a first semiconductor package including a first terminal and a second terminal provided on a surface different from a surface on which the first terminal is formed; and a second semiconductor package including a third terminal connected to the first terminal, wherein the surface on which the first terminal is formed faces a surface on which the third terminal is formed.

### BRIEF DESCRIPTION OF THE DRAWINGS

FIGS. 1 and 2 illustrate conventional semiconductor packages.

FIG. 3 illustrates a semiconductor package in accordance with an embodiment of the present invention.

FIGS. 4 to 6 illustrate semiconductor packages in accordance with other embodiments of the present invention.

FIG. 7 is a plan view of FIGS. 4 to 6.

FIGS. 8 to 10 illustrate semiconductor packages in accordance with other embodiments of the present invention.

FIGS. 11 to 13 are plan views of FIGS. 8 to 10, respectively.

FIG. 14 is a plan view of a semiconductor package in accordance with another embodiment of the present invention.

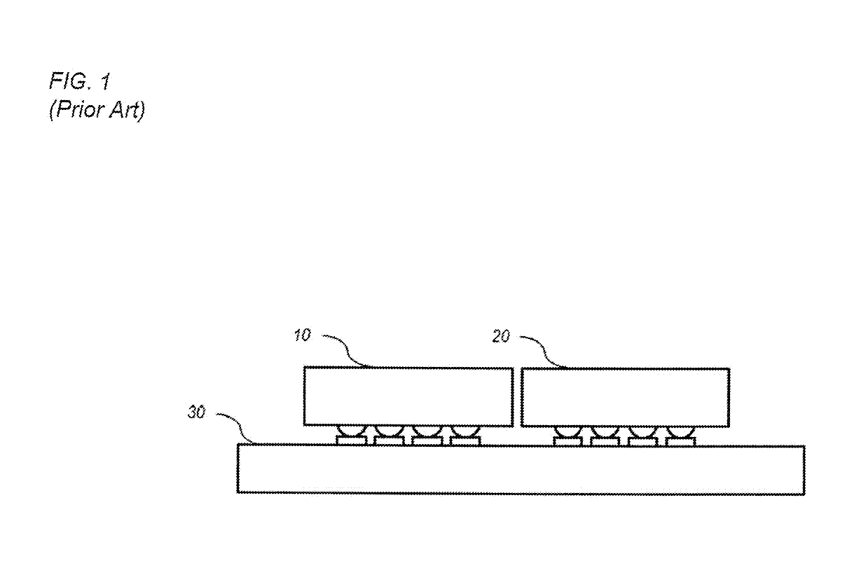

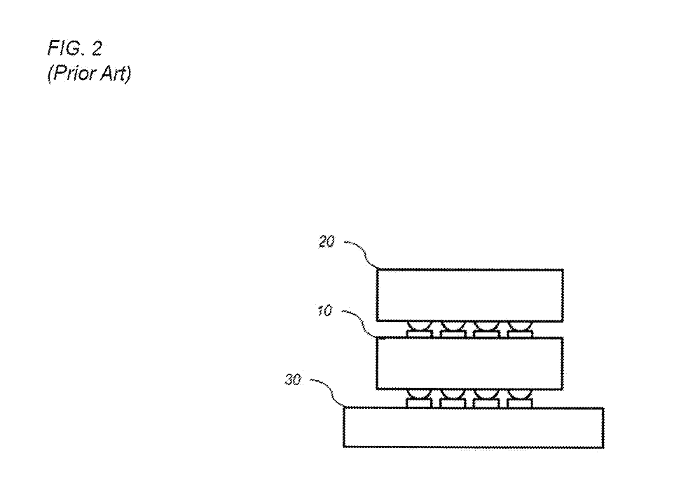

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

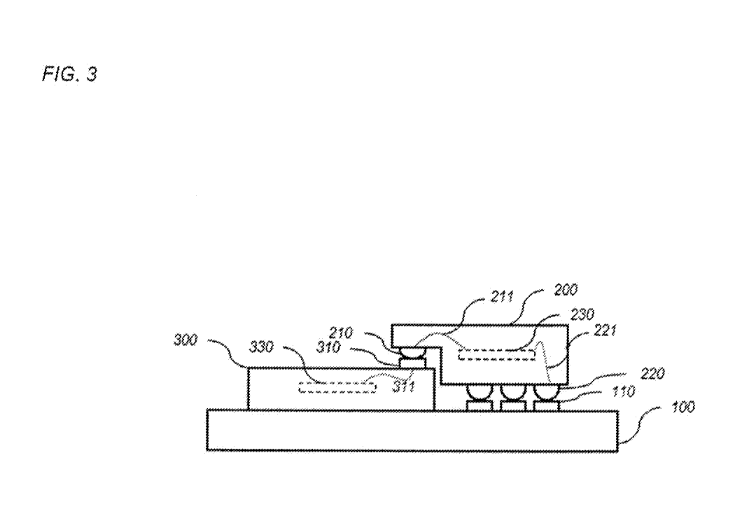

FIG. 3 illustrates a semiconductor package in accordance with an embodiment of the present invention.

Referring to FIG. 3, the semiconductor package in accordance with the embodiments of the present invention may include a first semiconductor package 200 and a second semiconductor package 300. The first semiconductor package 200 may include a first terminal 210 and a second terminal 220 formed on a surface different from a surface where the first terminal 210 is formed. The second semiconductor package 300 may include a third terminal 310. The surface where the first terminal 210 is formed faces a surface where the third terminal 310 is formed.

The first semiconductor package 200 has a stepped portion formed therein, on which the first terminal 210 is formed. FIG. 3 illustrates that the stepped portion is formed in substantially a “ [symbol] ” shape. However, the specific shape of the stepped portion may be easily modified by those skilled in the art.

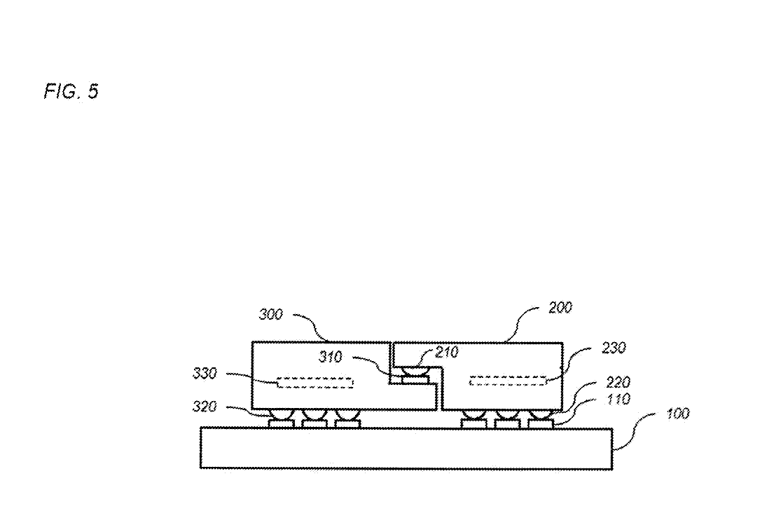

In FIG. 3, the second semiconductor package 300 does not include a stepped portion. In another embodiment, however, the second semiconductor package may also include a stepped portion on which a third terminal 310 may be formed. The embodiment will be described below with reference to FIG. 5.

FIG. 3 illustrates an example in which the first terminal 210 and the third terminal 310 are connected by a solder ball method. However, the shape of the terminals and the connection method may be easily modified and changed by those skilled in the art without departing the scope of the present invention.

The first and second semiconductor packages 200 and 300 may include first and second dies 230 and 330, respectively. The first die 230, the first terminal 210, and the second terminal 220 may be connected through signal lines 211 and 221 inside the first semiconductor package 200. The signal lines 211 and 221 may be formed of a conductive material. Furthermore, the second die 330 and the third terminal 310 may be connected through a signal line 311 inside the second semiconductor package 300. In the following drawings, it is obvious to those skilled in the art that a die and a terminal are connected through a signal line even though the signal line is not illustrated in the drawings.

The first terminal 210 may be directly connected to the third terminal 310 of the second semiconductor package 300 without passing through the substrate 100. Accordingly, interconnections (not illustrated) of the substrate 100 may be simplified, and interference from neighboring interconnections inside the substrate 100 may be reduced.

Referring to FIG. 3, the first and third terminals 210 and 310 may be positioned to face each other. However, the positions of the first and third terminals 210 and 310 are not necessarily limited to the structure of FIG. 3. For example, the first and third terminals 210 and 310 may be installed on side surfaces of the respective semiconductor package 200 and 300. In this case, however, the first and second semiconductor packages 200 and 300 may partially overlap each other, when seen from the top.

The second terminal 220 may be connected to a terminal 110 formed on the substrate 100. In the embodiment of FIG. 3, the second terminal 220 may be connected to the substrate thereunder. In another embodiment, however, another semiconductor package (not illustrate) or interposer (not illustrated) may be positioned under the first semiconductor package 200 such that the second terminal 220 may be connected to a terminal (not illustrated) formed on the semiconductor package or interposer.

The first die 230 embedded in the first semiconductor package 200 and the second die 330 embedded in the second semiconductor package 300 may not overlap each other, when seen from each other. This structure may reduce the possibility that another die will be deteriorated by heat generated by the respective semiconductor dies 230 and 330.

Furthermore, the connection point between the first and third terminals 210 and 310 may not overlap the first die 230, when seen from the top. This structure may prevent the first die 230 from being damaged by heat generated while the two terminals are bonded to each other. Similarly, the connection point between the first and third terminals 210 and 310 may not overlap the second die 330, when seen from the top.

Referring to FIG. 3, the first and second semiconductor packages 200 and 300 partially overlap each other, when seen from the top. Therefore, it is possible to reduce the area of the substrate by the overlapping area. Furthermore, it is possible to reduce the thickness of the semiconductor device, compared to a structure in which the semiconductor packages 200 and 300 are simply stacked vertically and connected to each other.

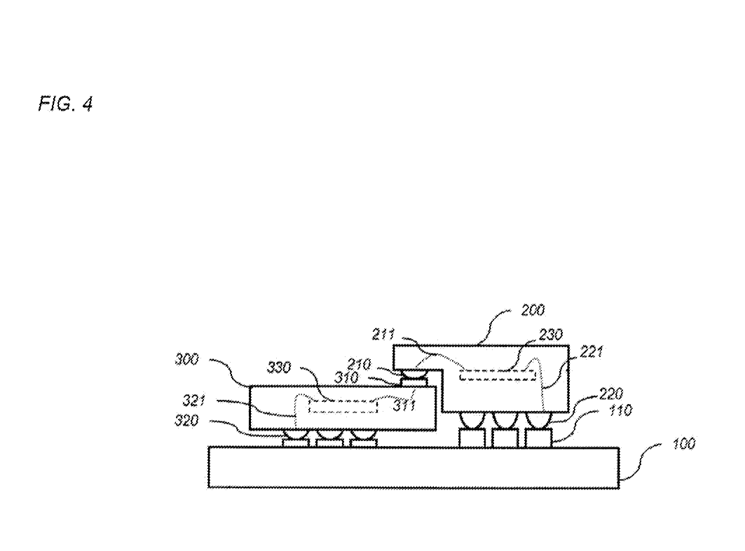

FIGS. 4 to 6 illustrate semiconductor packages in accordance with other embodiments of the present invention.

The embodiments of FIGS. 4 to 6 have substantially the same structure as the embodiment of FIG. 3, except that the second semiconductor package further may include a fourth terminal 320 (as seen in FIG. 5) formed on a surface different from the surface on which the third terminal 310 is formed.

The fourth terminal 320 may be connected to the second die 330 through a signal line 321. The fourth terminal 320 may be connected to a terminal formed on the substrate 100 positioned under the second semiconductor package 300, and connected to an interposer (not illustrated) positioned under the second semiconductor package 300 or a terminal (not illustrated) included in another semiconductor package (not illustrated).

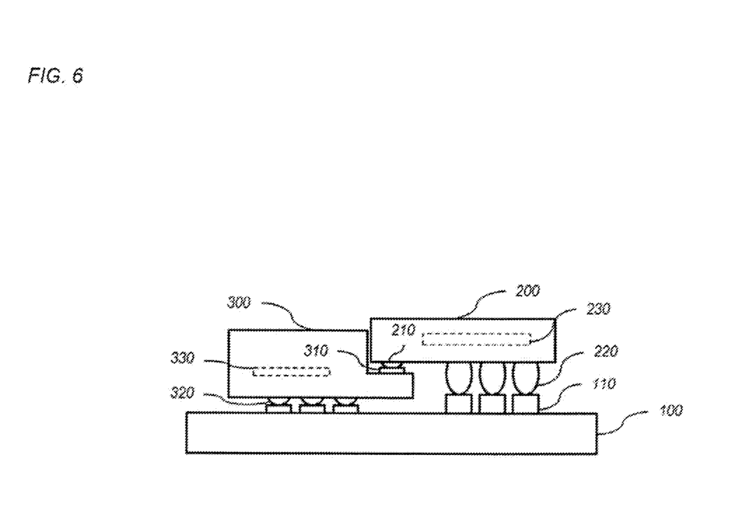

FIGS. 4 and 6 illustrate that any one of the first and second semiconductor packages 200 and 300 has a stepped portion formed therein, and FIG. 5 illustrates that both of the first and second semiconductor packages 200 and 300 have a stepped portion formed therein.

In the embodiments of FIGS. 3 to 6, signal lines 211, 221, 311, and 321 connected to the first to fourth terminals 210, 220, 310, and 320, respectively, may include a line for a typical operation or a line for a test operation. The line for a typical operation may include a data signal line. Furthermore, some of the signal lines, for example, the signal lines 211, 221, and 311 may serve as the line for a typical operation, and the other of the signal lines, for example, the signal line 321 may serve as the line for a test operation.

In the embodiments of FIGS. 3 to 6, the first die 230 embedded in the first semiconductor package 200 may include a logic chip such as a processor, for example, and the second die 330 embedded in the second semiconductor package 300 may include a memory chip such as DRAM, for example.

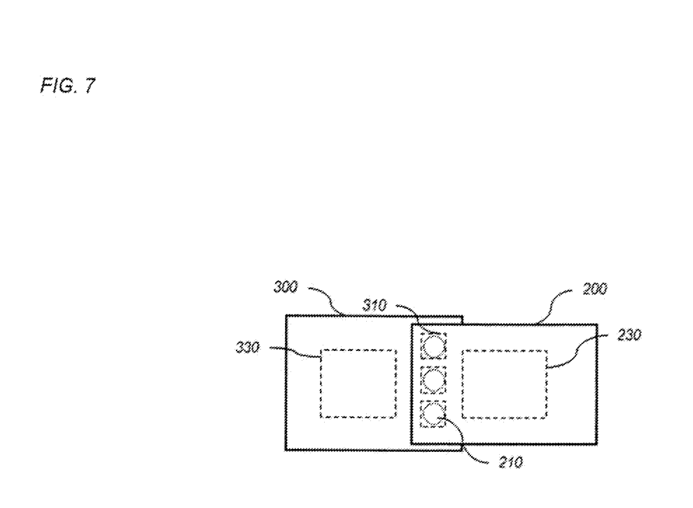

FIG. 7 is a plan view of FIGS. 4 to 6. In FIG. 7, the substrate is not illustrated.

As described above, the first and second dies 230 and 330 may not overlap each other, when seen from the top.

As described above, the connection point between the first semiconductor package 200 and the adjacent second semiconductor package 300, for example, a point where the first and third terminals 210 and 310 are directly connected to each other may not overlap the first die 230 embedded in the first semiconductor package 200. Furthermore, the connection point may not overlap the second die 330 embedded in the second semiconductor package 300.

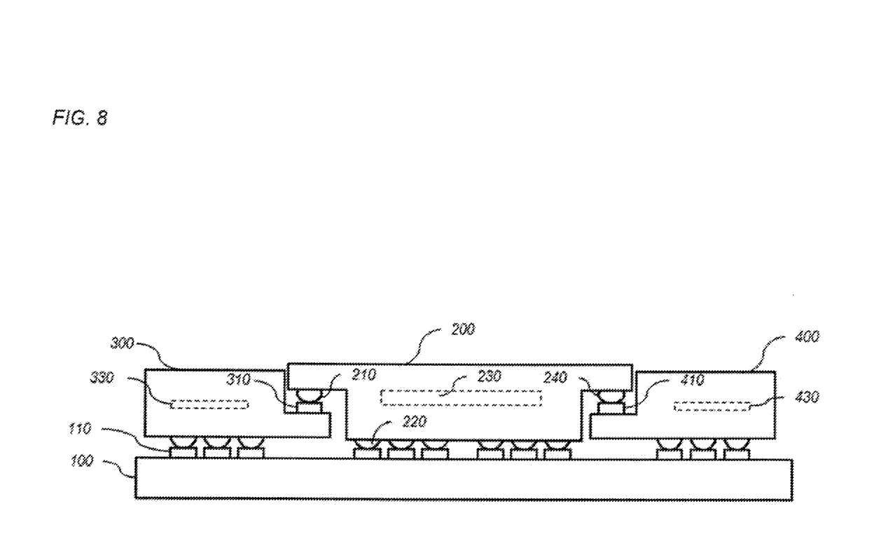

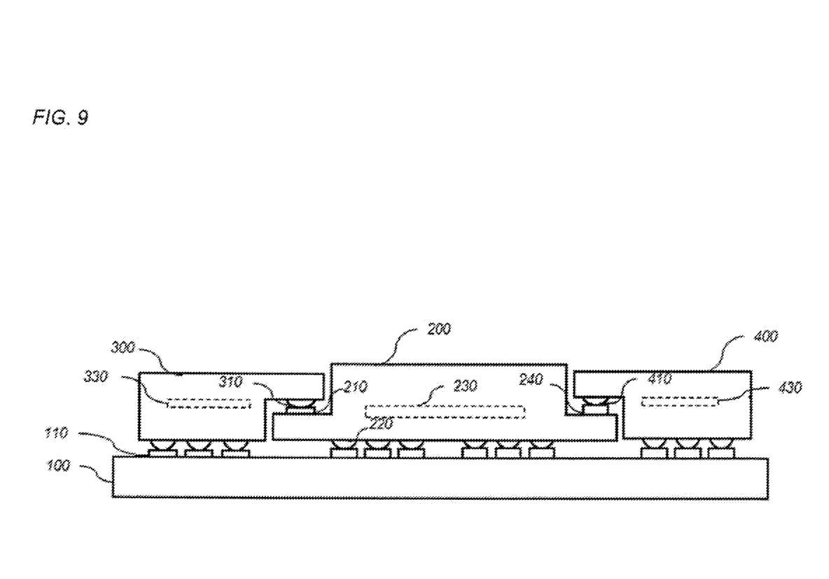

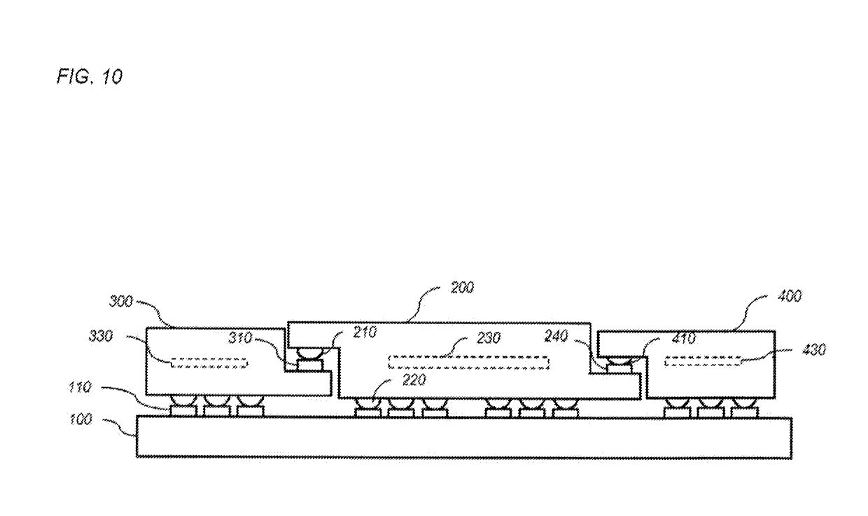

FIGS. 8 to 10 illustrate semiconductor packages in accordance with other embodiments of the present invention.

The embodiments of FIGS. 8 to 10 are different from the embodiments of FIGS. 4 to 6 in that the first semiconductor package 200 is adjacent to the second semiconductor package 300 and a third semiconductor package 400. Furthermore, the embodiments of FIGS. 8 to 10 share the technical idea of the present invention, except for the cross-sectional shapes of the respective semiconductor packages.

The first semiconductor package 200 further may include a sixth terminal 240 connected to a fifth terminal 410 formed in the third semiconductor package 400. The sixth terminal 240 may be connected to the fifth terminal 410 without passing through the substrate 100.

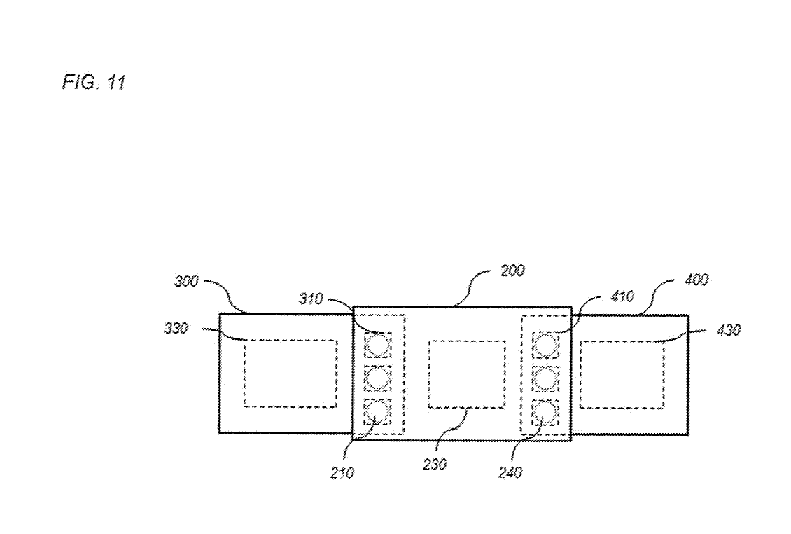

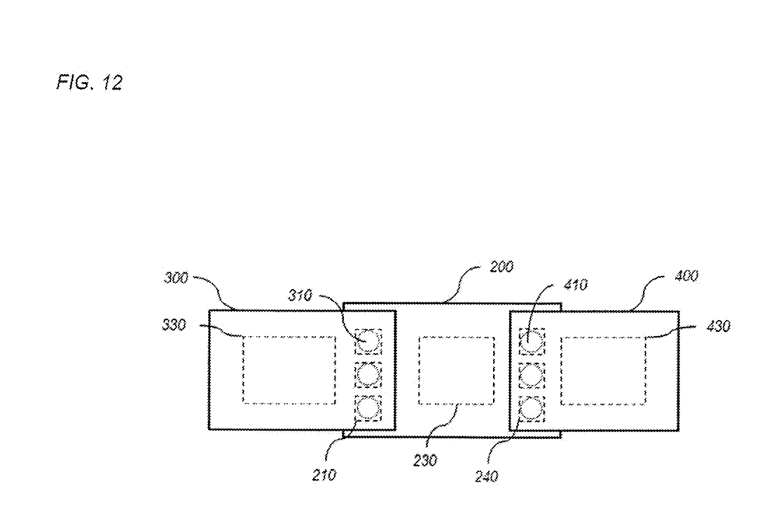

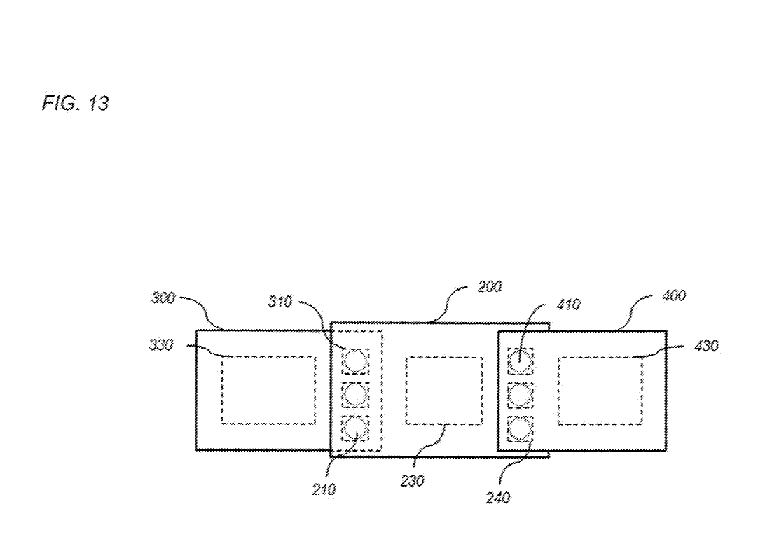

FIGS. 11 to 13 are plan views of FIGS. 8 to 10, respectively.

The first die 230 may not overlap a third die 430 provided in the third semiconductor package 400, when seen from the top.

The connection point between the fifth and six terminals 410 and 240 may not overlap the first die 230, when seen from the top. Furthermore, the connection point may not overlap the third die 430, when seen from the top.

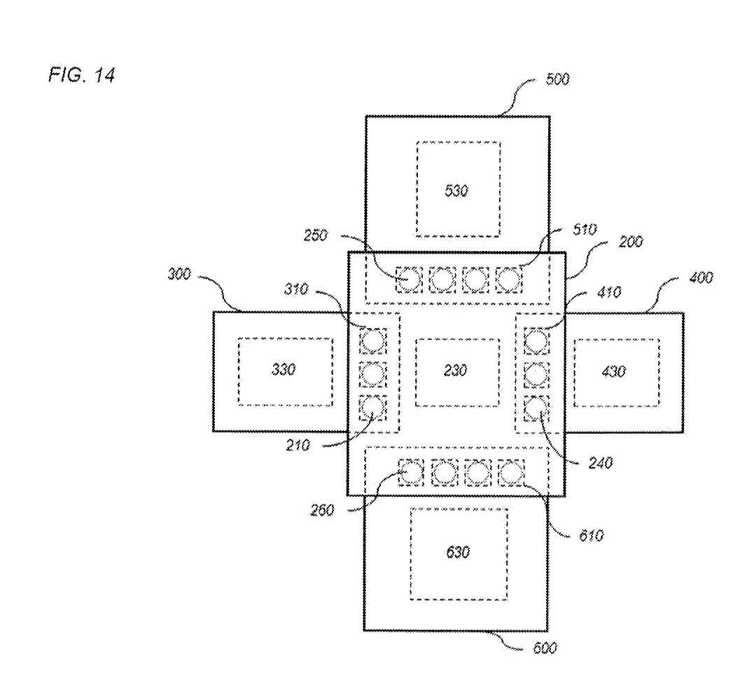

FIG. 14 is a plan view of a semiconductor package in accordance with various embodiments of the present invention.

In this embodiment of the present invention, the first semiconductor package 200 is adjacent to the second semiconductor package 300, the third semiconductor package 400, a fourth semiconductor package 500, and a fifth semiconductor package 600.

In these embodiments of the present invention, the first semiconductor package 200 further may include an eighth terminal 250 connected to a seventh terminal 510 of the fourth semiconductor package 500 and a tenth terminal 260 connected to a ninth terminal 610 of the fifth semiconductor package 600.

The first to fifth semiconductor packages may include stepped portions formed at overlapping portions therebetween, and the terminals may be formed in the stepped portions, respectively.

Referring to FIG. 14, the first die 230 embedded in the first semiconductor package 200 may not overlap the second to fifth dies 330, 430, 530, and 630 embedded in the second to fifth semiconductor packages 300 to 600, respectively.

In this embodiment of the present invention, the connection points between the first semiconductor package 200 and the second to fifth semiconductor packages 300 to 600 may not overlap the respective dies 230, 330, 430, 530, and 630, when seen from the top.

In the embodiments of FIGS. 8 to 14, the first die 230 embedded in the first semiconductor package 200 may include a logic chip such as a processor, and the dies embedded in the semiconductor packages adjacent to the first semiconductor package 200 may include a memory chip such as DRAM.

In accordance with the embodiments of the present invention, since a semiconductor package may be installed to overlap another semiconductor package adjacent thereto, it is possible to reduce the size of the substrate and the size of the system.

Furthermore, as the semiconductor package is installed to partially overlap the adjacent semiconductor package, it is possible to reduce the height of the system.

Furthermore, since the terminal of the semiconductor package connected to the adjacent semiconductor package does not pass through the substrate, the interconnections of the substrate may be simplified.

Furthermore, as the semiconductor package is installed to overlap the peripheral portion of the adjacent semiconductor package, it is possible to reduce heat transmitted to the adjacent semiconductor package.

Although various embodiments have been described for illustrative purposes, it will be apparent to those skilled in the art that various changes and modifications may be made without departing from the spirit and scope of the invention as defined in the following claims.

What is claimed is:

1. A semiconductor package comprising:
a first semiconductor package comprising a first terminal and a second terminal provided on a surface different from a surface on which the first terminal is formed; and
a second semiconductor package comprising a third terminal connected to the first terminal,
wherein the surface on which the first terminal is formed faces a surface on which the third terminal is formed.

2. The semiconductor package of claim 1, wherein the second semiconductor package further comprises a fourth terminal provided on a surface different from the surface on which the third terminal is formed.

3. The semiconductor package of claim 1, wherein the first semiconductor package has a stepped portion formed therein where the first semiconductor package is adjacent to the second semiconductor package, and the first terminal is formed on the stepped portion.

4. The semiconductor package of claim 1, wherein the second semiconductor package has a stepped portion formed therein where the second semiconductor package is adjacent to the first semiconductor package, and the third terminal is formed on the stepped portion.

5. The semiconductor package of claim 2, wherein the second and fourth terminals are connected to terminals provided on a substrate under the semiconductor package.

6. The semiconductor package of claim 2, wherein the second and fourth terminals are connected to an interposer under the semiconductor package or terminals provided on another semiconductor package.

7. The semiconductor package of claim 2, wherein the first semiconductor package comprises a first die provided therein, a first signal line connecting the first die and the first terminal, and a second signal line connecting the first die and the second terminal.

8. The semiconductor package of claim 7, wherein the first die does not overlap with a connection point of the first and third terminal.

9. The semiconductor package of claim 7, further comprising a second die provided in the second semiconductor package, a third signal line connecting the second die and the third terminal, and a fourth signal line connecting the second die and the fourth terminal.

10. The semiconductor package of claim 9, wherein the first die does not overlap with the second die.

11. The semiconductor package of claim 9, wherein the first to third signal lines comprise a signal line for data transmission, and the fourth signal line comprises a signal line for a test.

12. The semiconductor package of claim 9, wherein the first die comprises a logic chip, and the second die comprises a memory chip.

13. The semiconductor package of claim 1, wherein the first semiconductor package comprises a plurality of stepped portions formed thereon, and terminals are formed on the respective stepped portions.

14. The semiconductor package of claim 13, further comprising a plurality of semiconductor packages connected to the respective terminals.

15. The semiconductor package of claim 14, further comprising a first die provided in the first semiconductor package and a plurality of dies provided in the plurality of semiconductor packages, respectively.

16. The semiconductor package of claim 15, wherein a plurality of signal lines connecting the plurality of dies and the terminals formed on the respective stepped portions comprise a signal line for data transmission.

17. The semiconductor package of claim 15, wherein the first die comprises a logic chip, and the plurality of dies comprise a memory chip.

18. The semiconductor package of claim 15, wherein the first die and the plurality of dies do not overlap one another.

19. A mobile device including a semiconductor package comprising:
a first semiconductor package comprising a first terminal and a second terminal provided on a surface different from a surface on which the first terminal is formed; and
a second semiconductor package comprising a third terminal connected to the first terminal,
wherein the surface on which the first terminal is formed faces a surface on which the third terminal is formed.
